(19) United States
(12) Patent Application Publication
(10) Pub. No.: US 2024/0203729 A1
(43) Pub. Date: Jun. 20, 2024

(54) FILM FORMING METHOD AND FILM FORMING APPARATUS

(71) Applicant: Tokyo Electron Limited, Tokyo (JP)

(72) Inventor: Manabu HONMA, Oshu City (JP)

(21) Appl. No.: 18/539,451

(22) Filed: Dec. 14, 2023

(30) Foreign Application Priority Data
Dec. 20, 2022 (JP) 2022-203636

(51) Int. Cl. H01L 21/02; C23C 16/04; C23C 16/34; C23C 16/40

(52) U.S. Cl. CPC H01L 21/0228; C23C 16/04; C23C 16/345; C23C 16/401; H01L 21/02164; H01L 21/0217

(57) ABSTRACT

A film forming method includes executing a first cycle, which comprises adsorbing a raw material gas onto a substrate and reacting the raw material gas adsorbed onto the substrate with a reaction gas, a first number of times, supplying an adsorption inhibitor, which inhibits adsorption of the raw material gas on to the substrate, in a larger amount to a peripheral edge portion of the substrate than to a central portion, and executing a second cycle, which comprises the executing of the first cycle and the supplying of the adsorption inhibitor, a second number of times.

### CROSS-REFERENCE TO RELATED APPLICATION

This application is based upon and claims the benefit of priority from Japanese Patent Application No. 2022-203636, filed on Dec. 20, 2022, the entire contents of which are incorporated herein by reference.

### TECHNICAL FIELD

The present disclosure relates to a film forming method and a film forming apparatus.

### BACKGROUND

There is known a technique in which the in-plane thickness distribution of a film formed on a substrate is adjusted by controlling the balance of the flow rates of inert gas supplied from two suppliers (see, for example, Patent Document 1).

### PRIOR ART DOCUMENT

### Patent Document

Patent Document 1: Japanese Patent Laid-Open Publication No. 2020-74455

### SUMMARY

According to one embodiment of the present disclosure, there is provided a film forming method including executing a first cycle, which comprises adsorbing a raw material gas onto a substrate and reacting the raw material gas adsorbed onto the substrate with a reaction gas, a first number of times, supplying an adsorption inhibitor, which inhibits adsorption of the raw material gas on to the substrate, in a larger amount to a peripheral edge portion of the substrate than to a central portion, and executing a second cycle, which comprises the executing of the first cycle and the supplying of the adsorption inhibitor, a second number of times.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view illustrating a film forming apparatus according to an embodiment.

FIG. 2 is a schematic cross-sectional view illustrating a film forming apparatus according to the embodiment.

FIG. 3 is a flowchart illustrating a film forming method according to the embodiment.

FIGS. 4A to 4D are cross-sectional views illustrating the film forming method according to the embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, non-limiting exemplary embodiments of the present disclosure will be described with reference to the accompanying drawings. In all of the accompanying drawings, the same or corresponding members or components will be denoted by the same or corresponding reference numerals, and redundant descriptions will be omitted.

### [Film Forming Apparatus]

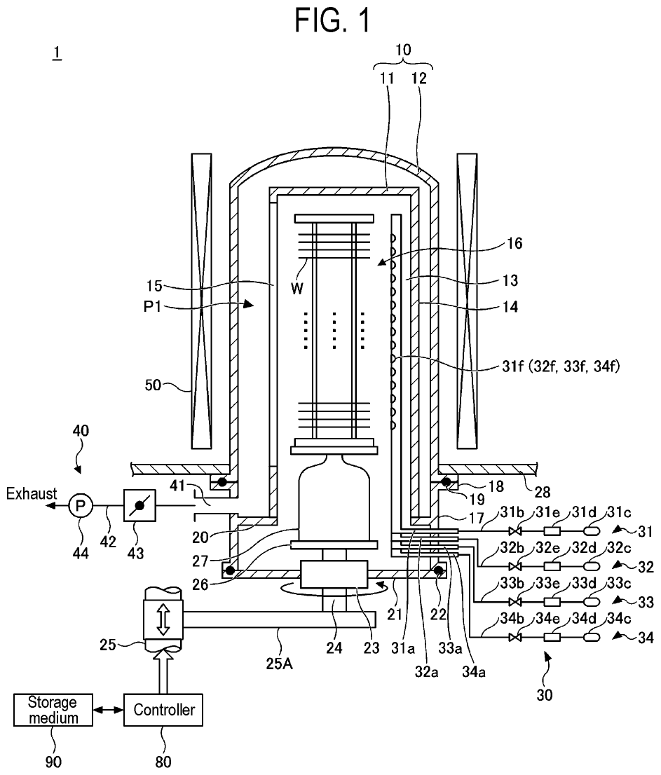

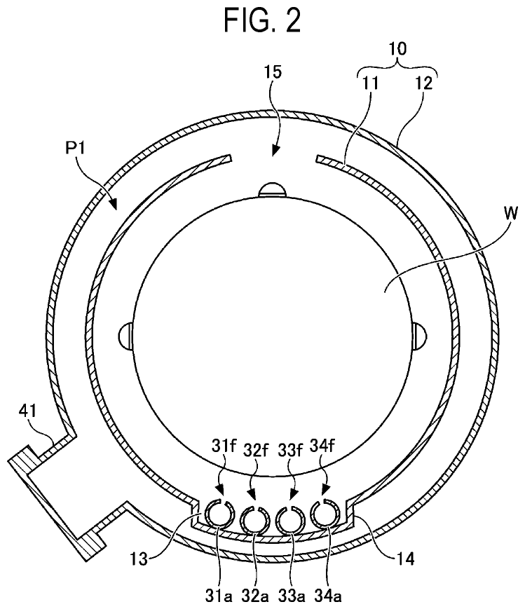

A film forming apparatus 1 according to an embodiment will be described with reference to FIGS. 1 and 2. FIGS. 1 and 2 are schematic cross-sectional views illustrating a film forming apparatus 1 according to an embodiment.

The film forming apparatus 1 is a batch-type apparatus that processes a plurality of substrates W at once. The substrates W are, for example, semiconductor wafers. The film forming apparatus 1 includes a processing container 10, a gas supplier 30, an exhauster 40, a heater 50, and a controller 80.

The interior of the processing container 10 can be depressurized. The processing container 10 accommodates the substrates W. The processing container 10 has an inner tube 11 and an outer tube 12. The inner tube 11 has a cylindrical shape having a ceiling and an open lower end. The outer tube 12 has a cylindrical shape having an open lower end and a ceiling and covers the outside of the inner tube 11. The inner tube 11 and the outer tube 12 are made of a heat-resistant material such as quartz. The inner tube 11 and the outer tube 12 have a coaxially arranged double tube structure.

In the side wall of the inner tube 11, an accommodation portion 13 is formed along the longitudinal direction (vertical direction) to accommodate a gas supply pipe. For example, a portion of the side wall of the inner tube 11 is made to protrude outward to form a convex portion 14, and the interior of the convex portion 14 is formed as the accommodation portion 13.

A rectangular opening 15 is formed in the side wall of the inner tube 11 along the longitudinal direction. The opening 15 faces the accommodation portion 13.

The opening 15 is a gas exhaust port that allows the gas inside the inner tube 11 to be exhausted therethrough. The opening 15 has the same length as a boat 16, or extends upward and downward to be longer than the length of the boat 16.

The lower end of the processing container 10 is supported by a cylindrical manifold 17. The manifold 17 is made of, for example, stainless steel. A flange 18 is formed at the upper end of the manifold 17. The flange 18 supports the lower end of the outer tube 12. A sealing member 19 such as an O-ring is provided between the flange 18 and the lower end of the outer tube 12. As a result, the interior of the outer tube 12 is hermetically maintained.

An annular support portion 20 is provided on the upper inner wall of the manifold 17. The support portion 20 supports the lower end of the inner tube 11. A lid 21 is hermetically installed to the opening at the lower end of the manifold 17 via a sealing member 22 such as an O-ring. As a result, the opening at the lower end of the processing container 10, i.e., the opening of the manifold 17, is hermetically closed. The lid 21 is made of, for example, stainless steel.

A rotary shaft 24 is provided through the center of the lid 21 via a magnetic fluid seal 23. The lower portion of the rotary shaft 24 is rotatably supported by an arm 25A of a lifting mechanism 25 configured as a boat elevator.

A rotary plate 26 is provided at the upper end of the rotary shaft 24. The boat 16, which holds substrates W are placed on the rotary plate 26 via a heat insulating pedestal 27 made of quartz. The boat 16 rotates by the rotation of the rotary shaft 24. The boat 16 is raised and lowered integrally with the lid 21 by raising and lowering the lifting mechanism 25. As a result, the boat 16 is inserted into and removed from the processing container 10. The boat 16 can be accommodated within the processing container 10. The boat 16 holds a plurality of (e.g., 50 to 150) substrates W in a shelf shape. The boat 16 holds the plurality of substrates W substantially horizontally with intervals in the vertical direction.

The gas supplier 30 is configured to introduce various processing gases into the inner tube 11. The gas supplier 30 includes a raw material gas supplier 31, a reaction gas supplier 32, an adsorption inhibitor supplier 33, and a purge gas supplier 34.

The raw material gas supplier 31 includes a raw material gas supply pipe 31a inside the processing container 10 and a raw material gas supply channel 31b outside the processing container 10. The raw material gas supply channel 31b is provided with a raw material gas source 31c, a mass flow controller 31d, and a valve 31e in that order from the upstream side to the downstream side in the gas flow direction. As a result, the supply timing of the raw material gas from the raw material gas source 31c is controlled by the valve 31e, and the flow rate is adjusted to a predetermined flow rate by the mass flow controller 31d. The raw material gas flows into the raw material gas supply pipe 31a from the raw material gas supply channel 31b, and is ejected into the processing container 10 from the raw material gas supply pipe 31a.

The reaction gas supplier 32 includes a reaction gas supply pipe 32a inside the processing container 10 and a reaction gas supply channel 32b outside the processing container 10. The reaction gas supply channel 32b is provided with a reaction gas source 32c, a mass flow controller 32d, and a valve 32e in that order from the upstream side to the downstream side in the gas flow direction. As a result, the supply timing of the reaction gas from the reaction gas source 32c is controlled by the valve 32e, and the flow rate is adjusted to a predetermined flow rate by the mass flow controller 32d. The reaction gas flows into the reaction gas supply pipe 32a from the reaction gas supply channel 32b, and is ejected into the processing container 10 from the reaction gas supply pipe 32a. The reaction gas is a gas that reacts with the raw material gas to produce a reaction product.

The adsorption inhibitor supplier 33 includes an adsorption inhibitor supply pipe 33a inside the processing container 10 and an adsorption inhibitor supply channel 33b outside the processing container 10. The adsorption inhibitor supply channel 33b is provided with an adsorption inhibitor source 33c, a mass flow controller 33d, and a valve 33e in that order from the upstream side to the downstream side in the gas flow direction. As a result, the supply timing of the adsorption inhibitor from the adsorption inhibitor source 33c is controlled by the valve 33e, and the flow rate is adjusted to a predetermined flow rate by the mass flow controller 33d. The adsorption inhibitor flows into the adsorption inhibitor supply pipe 33a from the adsorption inhibitor supply channel 33b, and is ejected into the processing container 10 from the adsorption inhibitor supply pipe 33a. The adsorption inhibitor is a gas that inhibits the adsorption of the raw material gas onto the substrates W.

The purge gas supplier 34 includes a purge gas supply pipe 34a inside the processing container 10 and a purge gas supply channel 34b outside the processing container 10. The purge gas supply channel 34b is provided with a purge gas source 34c, a mass flow controller 34d, and a valve 34e in that order from the upstream side to the downstream side in the gas flow direction. As a result, the supply timing of the purge gas from the purge gas source 34c is controlled by the valve 34e, and the flow rate is adjusted to a predetermined flow rate by the mass flow controller 34d. The purge gas flows into the purge gas supply pipe 34a from the purge gas supply channel 34b, and is ejected into the processing container 10 from the purge gas supply pipe 34a. The purge gas may be, for example, an inert gas such as nitrogen gas or argon gas.

Respective gas supply pipes (the raw material gas supply pipe 31a, the reaction gas supply pipe 32a, the adsorption inhibitor supply pipe 33a, and the purge gas supply pipe 34a) are fixed to the manifold 17. Each gas supply pipe is made of, for example, quartz. Each gas supply pipe extends linearly in the vicinity of the inner tube 11 along the vertical direction, and is bent in an L-shape within the manifold 17 to extend horizontally, thereby penetrating the manifold 17. The gas supply pipes are arranged side by side along the circumferential direction of the inner tube 11 and are formed at the same height.

A plurality of ejection ports 31f are provided at a portion of the raw material gas supply pipe 31a located inside the inner tube 11. A plurality of ejection ports 32f are provided at a portion of the reaction gas supply pipe 32a located inside the inner tube 11. A plurality of ejection ports 33f are provided at a portion of the adsorption inhibitor supply pipe 33a located within the inner tube 11. A plurality of ejection ports 34f are provided at a portion of the purge gas supply pipe 34a located inside the inner tube 11.

The ejection ports 31f, 32f, 33f, and 34f are formed at predetermined intervals along the extending direction of respective gas supply pipes. Each of the ejection ports 31f, 32f, 33f, and 34f ejects gas horizontally toward a substrate W from an outside in the radial direction of the substrate W. Each of the ejection ports 31f, 32f, 33f, and 34f discharges gas parallel to the main surface of the substrate W. The interval between the ejection ports is set to be the same as, for example, the interval between the substrates W held on the boat 16. The position of each ejection port in the height direction is set, for example, at an intermediate position between vertically adjacent substrates W. In this case, each ejection port can efficiently supply gas to the facing surfaces between adjacent substrates W.

The gas supplier 30 may mix multiple types of gases and discharge the mixed gas from one gas supply pipe. Respective gas supply pipes (the raw material gas supply pipe 31a, the reaction gas supply pipe 32a, the adsorption inhibitor supply pipe 33a, and the purge gas supply pipe 34a) may have mutually different shapes or arrangements. The gas supplier 30 may further include a gas supplier that supplies another gas.

The raw material gas, the reaction gas, and the adsorption inhibitor are selected depending on the type of a film to be formed.

For example, when forming a silicon oxide film, an aminosilane-based gas is selected as the raw material gas, an oxidizing gas is selected as the reaction gas, and oxygen radicals are selected as the adsorption inhibitor. As the aminosilane-based gas, for example, diisopropylaminosilane (DIPAS) gas, trisdimethylaminosilane (3DMAS) gas, bis(tertiary butylaminosilane) (BTBAS) gas, and combinations thereof may be used. As the oxidizing gas, for example, O₂ gas, O₃ gas, H₂O gas, NO₂ gas, and combinations thereof may be used. The oxygen radicals may be generated outside the processing container 10 and supplied into the processing container 10, or may be generated inside the processing container 10.

For example, when forming a silicon nitride film, a halogen-containing silicon gas is selected as the raw material gas, a nitride gas is selected as the reaction gas, and halogen radicals or hydrogen radicals are selected as the adsorption inhibitor. As the halogen-containing silicon gas, for example, a fluorine-containing silicon gas such as SiF₄ gas, SiHF₃ gas, SiH₂F₂ gas, or SiH₃F gas, a chlorine-containing silicon gas such as SiCl₄ gas, SiHC₁₃ gas, SiH₂Cl₂ (DCS) gas, SiH₃Cl gas, or Si₂Cl₆ gas, a bromine-containing silicon gas such as SiBr₄ gas, SiHBr₃ gas, SiH₂Br₂ gas, or SiH₃Br gas, and a combination thereof may be used. As the nitriding gas, for example, NH₃ gas, N₂H₂ gas, N₂H₄ gas, and combinations thereof may be used. As the halogen radicals, fluorine radicals, chlorine radicals, bromine radicals, and a combination thereof may be used. The halogen radicals and hydrogen radicals may be generated outside the processing container 10 and supplied into the processing container 10, or may be generated inside the processing container 10.

The exhauster 40 exhausts gas that is exhausted from the inner tube 11 through the opening 15 and exhausted from a gas outlet 41 through the space PI between the inner tube 11 and the outer tube 12. The gas outlet 41 is formed in the upper side wall of the manifold 17 and above the support portion 20. An exhaust channel 42 is connected to the gas outlet 41. A pressure adjustment valve 43 and a vacuum pump 44 are sequentially installed in the exhaust channel 42 to exhaust the interior of the processing container 10.

The heater 50 is provided around the outer tube 12. The heater 50 is provided, for example, on a base plate 28. The heater 50 has a cylindrical shape to cover the outer tube 12. The heater 50 includes, for example, a heating element, and heats each substrate W in the processing container 10.

The controller 80 controls the operation of each component of the film forming apparatus 1. The controller 80 may be, for example, a computer. A computer program for operating each component of the film forming apparatus 1 is stored in a storage medium 90. The storage medium 90 may be a non-transitory computer readable storage device, for example, a flexible disk, a compact disk, a hard disk, a flash memory, or a DVD.

### [Film Forming Method]

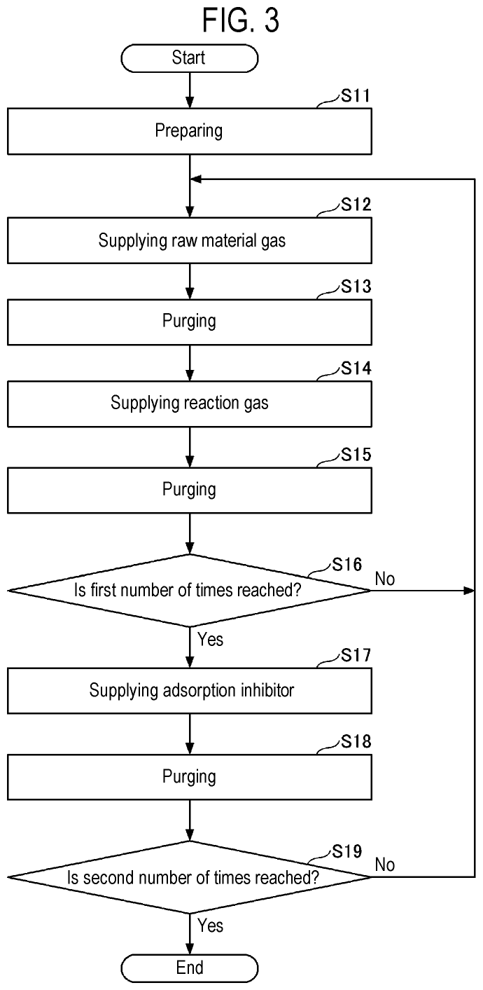

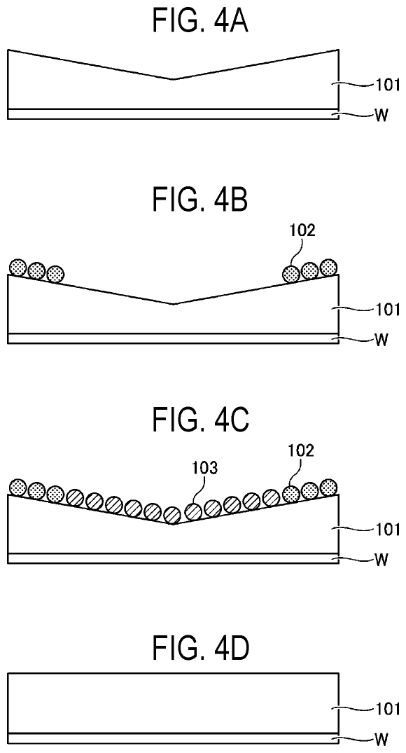

A film forming method according to an embodiment will be described with reference to FIGS. 3 and 4D. FIG. 3 is a flowchart illustrating a film forming method according to the embodiment. FIGS. 4A to 4D are cross-sectional views illustrating the film forming method according to the embodiment. Hereinafter, the film forming method according to the embodiment will be described below, taking as an example the case where the film forming method is implemented in the above-described film forming apparatus 1.

The film forming method according to the embodiment includes a preparation step S11, a raw material gas supply step S12, a purge step S13, a reaction gas supply step S14, a purge step S15, a first determination step S16, an adsorption inhibitor supply step S17, a purge step S18, and a second determination step S19.

In the preparation step S11, the controller 80 controls the lifting mechanism 25 to carry the boat 16 holding a plurality of substrates W into the processing container 10, and hermetically closes the opening at the lower end of the processing container 10 by the lid 21. Subsequently, the controller 80 controls the exhauster 40 to cause the interior of the processing container 10 to have a desired pressure, and controls the heater 50 to cause the interior of the processing container 10 to have a desired temperature. The controller 80 may rotate the boat 16 by rotating the rotary shaft 24.

The raw material gas supply step S12 is executed after the preparation step S11. In the raw material gas supply step S12, the controller 80 controls the mass flow controller 31d and the valve 31e to supply the raw material gas from the raw material gas supply pipe 31a into the processing container 10 at a desired flow rate. As a result, the raw material gas is adsorbed onto the surfaces of substrates W.

The purge step S13 is executed after the raw material gas supply step S12. In the purge step S13, the controller 80 controls the mass flow controller 34d and the valve 34e to supply purge gas from the purge gas supply pipe 34a into the processing container 10 at a desired flow rate. As a result, the raw material gas remaining in the processing container 10 is replaced with the purge gas. The purge step S13 may include evacuating the interior of the processing container 10.

The reaction gas supply step S14 is executed after the purge step S13. In the reaction gas supply step S14, the controller 80 controls the mass flow controller 32d and the valve 32e to supply the reaction gas from the reaction gas supply pipe 32a into the processing container 10 at a desired flow rate. As a result, the reaction gas reacts with the raw material gas adsorbed onto the surfaces of the substrates W, and a reaction product is produced.

The purge step S15 is executed after the reaction gas supply step S14. In the purge step S15, the controller 80 controls the mass flow controller 34d and the valve 34e to supply purge gas from the purge gas supply pipe 34a into the processing container 10 at a desired flow rate. As a result, the reaction gas remaining in the processing container 10 is replaced with the purge gas. The purge step S15 may include evacuating the interior of the processing container 10.

The first determination step S16 is executed after the purge step S15. In the first determination step S16, the controller 80 determines whether the steps from the raw material gas supply step S12 to the purge step S15 have been executed a first number of times. When the number of times of execution has not reached the first number of times (“NO” in the first determination step S16), the controller 80 controls the operation of each component of the film forming apparatus 1 to execute the steps from the raw material gas supply step S12 to the purge step S15 again. When the number of times of execution has reached the first number (“YES” in the first determination step S16), the controller 80 advances the process to the adsorption inhibitor supply step S17. In this way, a first cycle of performing the steps from the raw material gas supply step S12 to the purge step S15 in that order is repeated until the number of times of execution reaches the first number. The first number of times may be one time, or two or more times. The first number of times may be changed while executing a second cycle, which will be described later, a second number of times. For example, the first number of times may be decreased while executing the second cycle the second number of times. In the first half of the second cycle, which is executed the second number of times, the first number of times may be n times (n is a natural number of 2 or more), and in the second half of the second cycle, which is executed the second number of times, the first number of times may be m times (m is a natural number smaller than n). The first number of times may be increased while executing the second cycle the second number of times.

The adsorption inhibitor supply step S17 is executed after the first determination step S16. In the adsorption inhibitor supply step S17, the controller 80 controls the mass flow controller 33d and the valve 33e to supply the adsorption inhibitor from the adsorption inhibitor supply pipe 33a into the processing container 10 at a desired flow rate. In the adsorption inhibitor supply step S17, more adsorption inhibitor is adsorbed to the peripheral edge portions of the substrates W than to the central portions. For example, by using an adsorption inhibitor having a higher molecular weight and viscosity than the raw material gas, more adsorption inhibitor can be adsorbed to the peripheral edge portions of the substrates W than to the central portions. For example, by adjusting the pressure inside the processing container 10 and the flow rate of the adsorption inhibitor, more adsorption inhibitor can be adsorbed to the peripheral edge portions of the substrates W than to the central portions.

The purge step S18 is executed after the adsorption inhibitor supply step S17. In the purge step S18, the controller 80 controls the mass flow controller 34d and the valve 34e to supply purge gas from the purge gas supply pipe 34a into the processing container 10 at a desired flow rate. As a result, the adsorption inhibitor remaining in the processing container 10 is replaced with the purge gas. The purge step S18 may include evacuating the interior of the processing container 10.

The second determination step S19 is executed after the purge step S18. In the second determination step S19, the controller 80 determines whether the steps from the raw material gas supply step S12 to the purge step S18 have been executed a second number of times. When the number of times of execution has not reached the second number of times (“NO” in the second determination step S19), the controller 80 controls the operation of each component of the film forming apparatus 1 to execute the steps from the raw material gas supply step S12 to the purge step S18 again. When the number of times of execution has reached the second number of times (“YES” in the second determination step S19), the controller 80 controls the operation of each component of the film forming apparatus 1 to increase the pressure inside the processing container 10 to atmospheric pressure and to unload the boat 16 from the interior of the processing container 10. In this way, the steps from the raw material gas supply step S12 to the purge step S18 are repeated until the number of times of execution reaches the second number of times. The second number of times is determined depending on the target thickness of a film to be formed. The second number of times is, for example, two or more times. With the above, the film forming method according to the embodiment is completed.

On the other hand, when the gap between adjacent substrates W is narrow in the film forming apparatus 1 in which a plurality of substrates W are held in a shelf shape in the processing container 10, the raw material gas supplied into the processing container 10 from the raw material gas supply pipe 31a is difficult to flow into the gap. This is because the conductance of the gap is small, and the raw material gas easily flows into the space, which has a relatively large conductance, between the outer ends of the substrates W and the inner tube 11. In this case, it is difficult for the raw material gas to reach the central portions of the substrates W compared to the peripheral portions. In particular, when fine uneven patterns are formed on the surfaces of the substrates W, since a large amount of the raw material gas is consumed in the peripheral edge portions of the substrates W, it is difficult for the raw material gas to reach the central portions of the substrates W. Therefore, when the first cycle is executed the first number of times, the film is formed in a mortar-shape, with the film thickness in the central portion of each substrate W being smaller than the film thickness in the peripheral edge portion. When the raw material gas supply step S12 is executed under a condition under which self-limiting does not apply to the adsorption of the raw material gas onto the substrates W, the film thicknesses in the central portions of the substrates W tend to be smaller than the film thicknesses in the peripheral edge portions. The condition under which self-limiting does not apply means a condition in which the adsorption of the raw material gas onto the substrates W increases when the supply of the raw material gas is continued. On the other hand, the condition under which self-limiting applies means a condition under which self-limiting applies to the adsorption of the raw material gas onto the substrates W and the adsorption of the raw material gas does not increase even if the supply of the raw material gas is continued. In addition, a mortar-shaped film may also be formed due to insufficient activation of the raw material gas or a loading effect on the substrates W.

In the film forming method according to the embodiment, when the first cycle is executed the first number of times, a film having a mortar-shaped film thickness distribution is formed on each substrate W, as illustrated in FIG. 4A. Thereafter, by executing the adsorption inhibitor supply step S17, as illustrated in FIG. 4B, more adsorption inhibitor 102 is adsorbed onto the formed film 101 in the peripheral edge portion of the substrate W than in the central portion, reducing the number of adsorption sites in the peripheral edge portion of the substrate W. In this case, in the raw material gas supply step S12 executed after the adsorption inhibitor supply step S17, as illustrated in FIG. 4C, more raw material gas 103 is adsorbed in the central portion of the substrate W than in the peripheral edge portion. When the reaction gas supply step S14 is executed after the raw material gas supply step S12, the film 101 reflecting the in-plane distribution of the raw material gas 103 adsorbed on the substrate W is formed. Therefore, the film 101 is formed thicker in the central portion of the substrate W than in the peripheral edge portion. Therefore, the in-plane distribution of the film thickness is controlled by adjusting the supply concentration of the adsorption inhibitor supplied in the adsorption inhibitor supply step S17 and the first number of times, so that the film 101 having a small difference in thickness between the central portion and the peripheral edge portion of the substrate W can be formed, as illustrated in FIG. 4D. For example, by increasing the supply concentration of the adsorption inhibitor or decreasing the first number of times, the film thickness in the central portion of the substrate W can be made relatively greater. For example, by lowering the supply concentration of the adsorption inhibitor or increasing the first number of times, the film thickness in the peripheral edge portion of the substrate W can be made relatively greater.

For example, when forming a silicon oxide film, an aminosilane-based gas is selected as the raw material gas, an oxidizing gas is selected as the reaction gas, and oxygen radicals are selected as the adsorption inhibitor. In this case, when the first cycle is executed the first number of times, a silicon oxide film having a mortar-shaped film thickness distribution is formed on the substrate W, and hydroxyl groups (OH groups) are generated on the outermost surface of the substrate W. Thereafter, in the adsorption inhibitor supply step S17, more oxygen radicals are supplied to the peripheral edge portion of the substrate W than to the central portion, and hydrogen atoms are desorbed from some of the hydroxyl groups generated on the outermost surface of the substrate W, and more hydroxyl groups are left in the central portion of the substrate W than in the peripheral edge portion. Since an aminosilane-based gas is easily adsorbed to hydroxyl groups, more aminosilane-based gas is adsorbed in the central portion of the substrate W than in the peripheral edge portion in the raw material gas supply step S12 executed after the adsorption inhibitor supply step S17. In the reaction gas supply step S14 executed after the raw material gas supply step S12, the aminosilane-based gas adsorbed onto the substrate W is oxidized to form a silicon oxide film reflecting the in-plane distribution of the aminosilane-based gas adsorbed onto the substrate W. Therefore, by adjusting the supply concentration of the oxygen radicals supplied in the adsorption inhibitor supply step S17 and the first number of times, the in-plane distribution of the film thickness is controlled so that a silicon oxide film having a small difference in thickness between the central portion and the peripheral edge portion of the substrate W can be formed.

For example, when forming a silicon nitride film, a halogen-containing silicon gas is selected as the raw material gas, a nitride gas is selected as the reaction gas, and halogen radicals are selected as the adsorption inhibitor. In this case, when the first cycle is executed the first number of times, a silicon nitride film having a mortar-shaped film thickness distribution is formed on the substrate W, and amino groups (NH₂ groups) are generated on the outermost surface of the substrate W. Thereafter, in the adsorption inhibitor supply step S17, more halogen radicals are supplied to the peripheral edge portion of the substrate W than to the central portion, and the halogen is adsorbed to some of the amino groups generated on the outermost surface of the substrate W, so that more amino groups are left in the central portion of the substrate W than in the peripheral portion. Since a halogen-containing silicon gas is easily adsorbed to amino groups, more halogen-containing silicon gas is adsorbed in the central portion of the substrate W than in the peripheral edge portion in the raw material gas supply step S12 executed after the adsorption inhibitor supply step S17. In the reaction gas supply step S14 executed after the raw material gas supply step S12, the halogen-containing silicon gas adsorbed onto the substrate W is nitrided to form a nitride silicon film reflecting the in-plane distribution of the halogen-containing silicon gas adsorbed onto the substrate W. Therefore, by adjusting the supply concentration of halogen radicals supplied in the adsorption inhibitor supply step S17 and the first number of times, the in-plane distribution of the film thickness is controlled so that a silicon nitride film having a small difference in thickness between the central portion of the peripheral edge portion of the substrate W can be formed.

For example, when forming a silicon nitride film, a halogen-containing silicon gas may be selected as the raw material gas, a nitride gas may be selected as the reaction gas, and hydrogen radicals may be selected as the adsorption inhibitor. In this case, when the first cycle is executed the first number of times, a silicon nitride film having a mortar-shaped film thickness distribution is formed on the substrate W, and amino groups are generated on the outermost surface of the substrate W. Thereafter, in the adsorption inhibitor supply step S17, more hydrogen radicals are supplied to the peripheral edge portion of the substrate W than to the central portion, and hydrogen atoms are desorbed from some of the amino groups generated on the outermost surface of the substrate W, and more amino groups are left in the central portion of the substrate W than in the peripheral edge portion. Since a halogen-containing silicon gas is easily adsorbed to amino groups, more halogen-containing silicon gas is adsorbed in the central portion of the substrate W than in the peripheral edge portion in the raw material gas supply step S12 executed after the adsorption inhibitor supply step S17. In the reaction gas supply step S14 executed after the raw material gas supply step S12, the halogen-containing silicon gas adsorbed onto the substrate W is nitrided to form a nitride silicon film reflecting the in-plane distribution of the halogen-containing silicon gas adsorbed onto the substrate W. Therefore, by adjusting the supply concentration of halogen radicals supplied in the adsorption inhibitor supply step S17 and the first number of times, the in-plane distribution of the film thickness is controlled so that a silicon nitride film having a small difference in thickness between the central portion of the peripheral edge portion of the substrate W can be formed.

It is to be considered that the embodiments disclosed herein are exemplary in all respects and not restrictive. Various types of omissions, replacements, and changes may be made to the above-described embodiments without departing from the scope and spirit of the appended claims.

In the above-described embodiments, the case in which the processing container is a container having a double-tube structure has been described, but the present disclosure is not limited thereto. For example, the processing container may be a container having a single-tube structure.

According to the present disclosure, the in-plane distribution of a film thickness can be controlled.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method comprising:
executing a first cycle, which comprises adsorbing a raw material gas onto a substrate and reacting the raw material gas adsorbed onto the substrate with a reaction gas, a first number of times;
supplying an adsorption inhibitor, which inhibits adsorption of the raw material gas on to the substrate, in a larger amount to a peripheral edge portion of the substrate than to a central portion; and
executing a second cycle, which comprises the executing of the first cycle and the supplying of the adsorption inhibitor, a second number of times.

2. The film forming method of claim 1, wherein the executing of the first cycle is performed under a condition where self-limiting does not apply to the adsorption of the raw material gas onto the substrate.

3. The film forming method of claim 2, wherein the executing of the first cycle comprises generating hydroxyl groups on the substrate, and
wherein the supplying of the adsorption inhibitor comprises desorbing hydrogen atoms from some of the hydroxyl groups generated on the substrate, so that more hydroxyl groups are left in the central portion of the substrate than in the peripheral edge portion.

4. The film forming method of claim 1, wherein the first number of times is once.

5. The film forming method of claim 1, wherein the first number of times is twice or more.

6. The film forming method of claim 1, wherein the first number of times is changed while executing the second cycle the second number of times.

7. The film forming method of claim 1, wherein the raw material gas is ejected toward the substrate from an outside in a radial direction of the substrate.

8. The film forming method of claim 1, wherein the executing of the first cycle comprises generating hydroxyl groups on the substrate, and
the supplying of the adsorption inhibitor comprises desorbing hydrogen atoms from some of the hydroxyl groups generated on the substrate, so that more hydroxyl groups are left in the central portion of the substrate than in the peripheral edge portion.

9. The film forming method of claim 1, wherein the executing of the first cycle comprises generating amino groups on the substrate, and
the supplying of the adsorption inhibitor comprises desorbing hydrogen atoms from some of the amino groups generated on the substrate, so that more amino groups are left in the central portion of the substrate than in the peripheral edge portion.

10. The film forming method of claim 1, wherein the executing of the first cycle comprises generating amino groups on the substrate, and
the supplying of the adsorption inhibitor comprises adsorbing halogen to some of the amino groups generated on the substrate, so that more amino groups are left in the central portion of the substrate than in the peripheral edge portion.

11. A film forming apparatus comprising:
a processing container;
a gas supplier configured to supply a gas into the processing container; and
a controller,
wherein the controller is configured to perform:
executing a first cycle, which comprises adsorbing a raw material gas onto a substrate and reacting the raw material gas adsorbed onto the substrate with a reaction gas, a first number of times;
supplying an adsorption inhibitor, which inhibits adsorption of the raw material gas on to the substrate, in a larger amount to a peripheral edge portion of the substrate than to a central portion; and
executing a second cycle, which comprises the executing of the first cycle and the supplying of the adsorption inhibitor, a second number of times.
